(19) United States
(12) Patent Application Publication
(10) Pub. No.: US 2024/0339566 A1
(43) Pub. Date: Oct. 10, 2024

(54) MICRO LIGHT EMITTING DIODE DISPLAY DEVICE AND METHOD FOR MANUFACTURING SAME

(71) Applicant: Raysolve Optoelectronics (Suzhou) Company Limited, Suzhou (CN)

(72) Inventor: Wing Cheung CHONG, Suzhou (CN)

(73) Assignee: Raysolve Optoelectronics (Suzhou) Company Limited, Suzhou (CN)

(21) Appl. No.: 18/749,291

(22) Filed: Jun. 20, 2024

Related U.S. Application Data
(63) Continuation of application No. PCT/CN2022/126454, filed on Oct. 20, 2022.

(30) Foreign Application Priority Data
Dec. 20, 2021 (CN) 202111559295.2

(51) Int. Cl. H01L 33/24; H01L 25/075; H01L 33/00; H01L 33/44; H01L 33/62

(52) U.S. Cl. CPC H01L 33/24; H01L 25/0753; H01L 33/0093; H01L 33/0095; H01L 33/44; H01L 33/62; H01L 2933/0025; H01L 2933/0066

(57) ABSTRACT

The present application discloses a micro light emitting diode display device and a method for manufacturing the same. The device comprises an LED semiconductor layer, wherein the LED semiconductor layer comprises: a first doping type semiconductor layer; an active layer formed on the first doping type semiconductor layer; a second doping type semiconductor layer formed on the active layer; wherein the LED semiconductor layer is provided with a plurality of protrusions arranged in an array, and each of the protrusions corresponds to an LED unit, and each protrusion comprises an ion injection region and a non-ion injection region, wherein the non-ion injection region forms an LED mesa, and the ion injection region surrounds the LED mesa, and each protrusion has an arc-shaped light-emitting surface capable of collimating the light emitted by the active layer.

### CROSS-REFERENCE TO RELATED APPLICATIONS

The application claims priority to Chinese patent application No. 202111559295.2, filed on Dec. 20, 2021, the entire contents of which are incorporated herein by reference.

### TECHNICAL FIELD

The present application relates to the field of micro-display, and in particular to a micro light emitting diode (LED) display device and a method for manufacturing the same.

### BACKGROUND

A display device in the field of micro-display is mostly used to generate high-brightness miniature display images, which are projected by optical system and perceived by observers, and a projection target can be retina (virtual image) or projection curtain (real image). It can be applied to AR (Augmented Reality), HUD (Car Head Up Display) and other aspects.

The emerging technology mainly relates to Micro-LED micro-display devices. In the conventional technology, since light emitted by LEDs is spontaneously emitted, it has no directionality and a large scattering angle, which is likely to cause optical crosstalk between the adjacent LEDs, and is not favorable for customers' requirements for high brightness of the micro display device.

The information disclosed in the background is only intended to increase the understanding of the general background of the present application, and should not be taken as an admission or any form of imply that the information constitutes the conventional technology that is known to those skilled in the art.

### SUMMARY

An object of the present application is to provide a micro light emitting diode display device and a method for manufacturing the same.

In order to achieve the above object, a micro light emitting diode display device is provided according to an embodiment of the present application, including an LED semiconductor layer. The LED semiconductor layer includes:
a first doping type semiconductor layer;
an active layer formed on the first doping type semiconductor layer;
a second doping type semiconductor layer formed on the active layer;
where the LED semiconductor layer is provided with multiple protrusions arranged in an array, and each of the multiple protrusions corresponds to one LED unit,
the protrusion includes an ion injection region and a non-ion injection region, where the non-ion injection area forms an LED mesa, the ion injection area surrounds the LED mesa, and the protrusion is provided with an arc-shaped light-emitting surface capable of collimating light emitted by the active layer.

Preferably, in the micro light emitting diode display device, the protrusions are formed by the second doping type semiconductor layer, and each of the protrusions is combined with the active layer and the first doping type semiconductor layer to form an LED unit.

Preferably, in the micro light emitting diode display device, the protrusions are formed by the second doping type semiconductor layer and the active layer, and each of the protrusions is combined with the first doping type semiconductor layer to form an LED unit.

Preferably, in the micro light emitting diode display device, the protrusions are formed by the second doping type semiconductor layer, the active layer and the first doping type semiconductor layer, and each of the protrusions forms an LED unit.

Preferably, the micro light emitting diode display device further includes a substrate, where the LED semiconductor layer is arranged on the substrate through a bonding layer, and the bonding layer is formed between the substrate and the first doped semiconductor. The substrate includes driving circuits and multiple contacts electrically connected with the driving circuits, each of the LED units corresponds to one contact, and the contacts drive the LED units.

Preferably, in the micro light emitting diode display device described above, the contacts are electrically connected with the second doping type semiconductor layer of each LED unit, and the contacts are located between the adjacent LED units. The micro light emitting diode display device further includes an electrode connection structure, and the contacts are electrically connected with the second doping type semiconductor layer of each LED unit through an electrode connection structure.

Preferably, in the micro light emitting diode display device described above, the electrode connection structure includes.
multiple through holes passing through the LED semiconductor layer and the bonding layer, where each of the through holes corresponds to one of the contacts, and the contacts are exposed at the bottom portion of the through holes;
a passivation layer formed on the second doping type semiconductor layer, where a first opening exposing the LED mesa and a second opening exposing the contacts are formed on the passivation layer;
an electrode layer formed on the passivation layer, and electrically connected to the second doping type semiconductor layer through the first opening and electrically connected to the contact through the second opening.

Preferably, in the micro light emitting diode display device, all of the LED units share the same first doping type semiconductor layer.

Preferably, in the micro light emitting diode display device, the through hole includes a first through hole passing through the LED semiconductor layer and exposing a surface of the bonding layer.

The through hole further includes a second through hole passing through the bonding layer and exposing the contact.

The first through hole and the second through hole are communicated with each other and are both in stepped shape.

Preferably, in the micro light emitting diode display device, the through hole is a straight hole passing through the LED semiconductor layer and the bonding layer.

Preferably, in the micro light emitting diode display device, an isolation groove is formed between the adjacent LED units, and the isolation groove passes through the LED semiconductor layer and the bonding layer for electrical isolation,

Each of the contacts is located below a corresponding LED unit and electrically connected with the first doping type semiconductor layer through the conductive bonding layer,

The second doping type semiconductor layers of the multiple LED units share an electrode through an electrode layer.

Preferably, in the micro light emitting diode display device, the LED mesa is arranged at a center of the corresponding protrusion.

Preferably, in the micro light emitting diode display device, an outer diameter D of the protrusion and an outer diameter d of the LED mesa satisfy: d is less than D/2.

Preferably, in the micro light emitting diode display device, the ions injected in the ion injection region are hydrogen, helium, nitrogen, oxygen, fluorine, magnesium, silicon or argon ions.

Preferably, in the micro light emitting diode display device, the first doping type semiconductor layer is a p-type semiconductor layer, and the second doping type semiconductor layer is an n-type semiconductor layer, or
the first doping type semiconductor layer is an n-type semiconductor layer, and the second doping type semiconductor layer is a p-type semiconductor layer.

In order to achieve the above objection, a method for manufacturing a micro light emitting diode display device is provided according to an embodiment of the present application, which includes the following steps:
providing a first substrate, and forming an LED semiconductor layer on the first substrate, where the LED semiconductor layer includes a second doping type semiconductor layer, an active layer and a first doping type semiconductor layer which are sequentially formed;
providing a substrate, where the substrate includes driving circuits and multiple contacts electrically connected with the driving circuits;
arranging a bonding layer on the substrate and/or the first doping type semiconductor layer;
bonding the substrate and the first doping type semiconductor layer with each other through the bonding layer;
peeling off and removing the first substrate and then performing an ion injection operation to form an isolation material in the LED semiconductor layer, where the isolation material divides the LED semiconductor layer into multiple LED mesas; and
performing an etching operation to form multiple protrusions arranged in an array on the LED semiconductor layer, where each of the protrusions includes the LED mesa and an ion injection region surrounded by the isolation material, and the protrusions are provided with arc-shaped light-emitting surfaces capable of collimating the light emitted by the active layer.

Preferably, in the method for manufacturing the micro light emitting diode display device, the method for forming the multiple protrusions arranged in an array on the LED semiconductor layer includes: etching the second doping type semiconductor layer to the surface of the active layer or a certain depth, forming the protrusions on the active layer, and combining each of the protrusions with the active layer and the first doping type semiconductor layer to form an LED unit.

Preferably, in the method for manufacturing the micro light emitting diode display device, the method for forming the multiple protrusions arranged in an array on the LED semiconductor layer includes: etching the second doping type semiconductor layer to the surface of the first doping type semiconductor layer or a certain depth, forming the protrusions on the first doping type semiconductor layer, and combining each of the protrusions with the first doping type semiconductor layer to form an LED unit.

Preferably, in the method for manufacturing the micro light emitting diode display device, the method for forming the multiple protrusions arranged in an array on the LED semiconductor layer includes: etching the second doping type semiconductor layer to the surface of the bonding layer, and forming the protrusions on the surface of the bonding layer, where each of the protrusions forms an LED unit.

Preferably, in the method for manufacturing the micro light emitting diode display device, the contacts are located between the adjacent protrusions, and the manufacturing method further includes manufacturing an electrode connection structure, and the contacts are electrically connected with the second doping type semiconductor layer of the protrusions through the electrode connection structure.

Preferably, in the method for manufacturing the micro light emitting diode display device, the method for manufacturing the electrode connection structure includes the following steps: etching the LED semiconductor layer and the bonding layer to form multiple through holes distributed in an array, where each of the through holes corresponds to one of the contacts, and the contacts are exposed at the bottom portion of the through holes; forming a passivation layer on the second doping type semiconductor layer, where the passivation layer is provided with a first opening exposing the LED mesa and a second opening exposing the contacts; and forming an electrode layer on the passivation layer, where the electrode layer is electrically connected with the second doping type semiconductor layer through the first opening and electrically connected with the contact through the second opening.

Preferably, in the method for manufacturing the micro light emitting diode display device, all of the LED units share the same first doping type semiconductor layer.

Preferably, in the method for manufacturing the micro light emitting diode display device, the method for forming multiple through holes distributed in an array on the LED semiconductor layer and the bonding layer includes the following steps: forming a first through hole between the adjacent protrusions by sequentially etching the active layer and the first doping type semiconductor layer; etching the bonding layer at the bottom portion of the first through hole to form a second through hole, exposing the contact, and communicating with the first through hole.

Preferably, in the method for manufacturing the micro light emitting diode display device, the method for forming multiple through holes distributed in an array on the LED semiconductor layer and the bonding layer includes: passing through the active layer, the first doping type semiconductor layer and the bonding layer respectively through one-time etching between the adjacent LED units.

Preferably, in the method for manufacturing the micro light emitting diode display device, the contact is located below the corresponding LED unit and electrically connected with the first doping type semiconductor layer through the conductive bonding layer, and the method further includes: forming an isolation groove between the adjacent LED units, where the isolation groove penetrates the active layer, the first doping type semiconductor layer and the bonding layer for electrical isolation; and manufacturing an electrode layer between the second doping type semiconductor layers of the multiple LED units, and the electrode layer is used as a common electrode.

Preferably, in the method for manufacturing the micro light emitting diode display device, the method for forming multiple protrusions arranged in an array on the LED semiconductor layer includes the following steps: manufacturing a precursor layer on the surface of the formed second doping type semiconductor layer, where the precursor layer is formed with a precursor matched with the shape of the protrusions; and etching the precursor layer and the LED semiconductor layer to transfer the shape of the precursor of the precursor layer from the precursor layer to the LED semiconductor layer.

Preferably, in the method for manufacturing the micro light emitting diode display device, the LED mesa is arranged in the center of the corresponding protrusion.

Preferably, in the method for manufacturing the micro light emitting diode display device, the outer diameter D of the protrusion and the outer diameter d of the LED mesa satisfy: d is less than D/2.

Preferably, in the method for manufacturing the micro light emitting diode display device, the ions include hydrogen, helium, nitrogen, oxygen, fluorine, magnesium, silicon or argon ions.

Preferably, in the method for manufacturing the micro light emitting diode display device, the first doping type semiconductor layer is a p-type semiconductor layer and the second doping type semiconductor layer is an n-type semiconductor layer, or the first doping type semiconductor layer is an n-type semiconductor layer and the second doping type semiconductor layer is a p-type semiconductor layer.

Compared with the conventional technology, in the present application, a protrusion for converging light for each LED mesa is etched and formed, which can effectively improve the collimation effect of emergent light and improve the display brightness of the micro light emitting diode display device.

### BRIEF DESCRIPTION OF DRAWINGS

FIG. 1 is a schematic structural view (sectional view along B-B in FIG. 2) of a light emitting diode according to Example 1 of the present application;

FIG. 2 is a top view of the light emitting diode according to Example 1 of the present application;

FIG. 3 is a schematic view of light ray emergence according to Example 1 of the present application;

FIG. 4A to FIG. 4H are cross-sectional views (sectional views along A-A in FIG. 2) showing illustrative light emitting diode structures at different stages in a manufacturing process according to Example 1 of the present application;

FIG. 5 is a schematic view showing a microlens structure manufactured by dry etching pattern transfer according to Example 2 of the present application;

FIG. 6 is a schematic structural view showing that an edge of an arc light-emitting surface extends to a surface of a first doping type semiconductor layer according to Example 3 of the present application;

FIG. 7 is a schematic structural view showing that the edge of the arc light-emitting surface extends to a surface of a bonding layer according to Example 4 of the present application;

FIG. 8 is a schematic structural view showing a through hole as a stepped hole according to Example 5 of the present application;

FIG. 9 is a schematic structural view of a common electrode of a second doping type semiconductor layer according to Example 6 of the present application.

### DETAILED DESCRIPTION OF THE EMBODIMENTS

While specific configurations and arrangements are discussed, it should be understood that this is done for illustrative purposes only. Accordingly, other configurations and arrangements may be used without departing from the scope of the present application. Moreover, the present application may also be employed in a variety of other applications. The functional and structural features described in the present application can be combined, adapted and modified in various ways with each other and not specifically shown in the drawings, so that these combinations, adaptations and modifications are within the scope of the present application.

In general, terms may be understood based at least in part on contextual usage. For example, the term “one or more” as used herein may be used to describe any element, structure, or feature in the singular or may be used to describe a combination of elements, structures or features in the plural, depending, at least in part, on the context. Similarly, terms such as “a,” “an,” or “the” may also be understood to convey singular usage or to convey plural usage, depending, at least in part, on the context. Additionally, the term “based on” may be understood as not necessarily intended to convey an exclusive set of factors, but may instead allow for the presence of additional factors that do not necessarily have to be explicitly described, depending at least in part on the context.

It should be readily understood that the meaning of one element “on”, “above”, and “over” the other element in the present application should be interpreted in the broadest sense such that one element “on” the other element not only means one element “directly on” the other element, but also means one element “on” the other element with intermediate members or layers therebetween, and one element “above” or “over” the other element not only means one element “above” or “over” the other element, but also means one element “above” or “over” the other element without the intermediate members or layers therebetween (that is, one element directly on the other element).

Furthermore, spatially relative terms, such as “below”, “beneath”, “lower”, “above”, “upper” and the like may be used herein for ease of description to describe relationship between one element or component to another element or component as illustrated in the figures. The spatially relative terms are intended to encompass different orientations of the device in use or operation in addition to the orientation depicted in the figures. The device may be otherwise oriented (rotated 90° or at other orientations) and the spatially relative descriptors used herein interpreted accordingly.

The term “layer” as used herein refers to a portion of material that includes a region having a thickness. The layer may extend over the entire underlying or overlying structure, or may have a lesser extent than the extent of the underlying or overlying structure. Furthermore, a layer may be a region of a homogeneous or heterogeneous continuous structure having a thickness less than the thickness of the continuous structure. For example, a layer may be located between any pair of horizontal planes between a top surface and a bottom surface of a continuous structure or therebetween. The layer may extend horizontally, vertically, and/or along the tapered surface. The substrate may be a layer, may include one or more layers therein, and/or may have one or more layers above, and/or below it. A layer may include multiple layers. For example, the semiconductor layer may include one or more doped or undoping type semiconductor layers, and may be of the same or different materials.

### Example 1

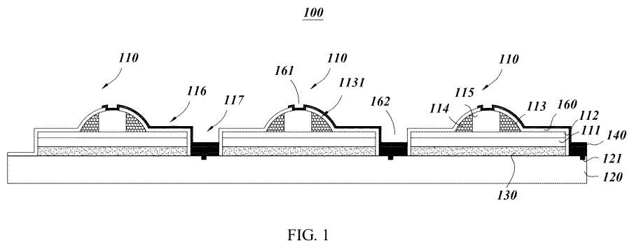

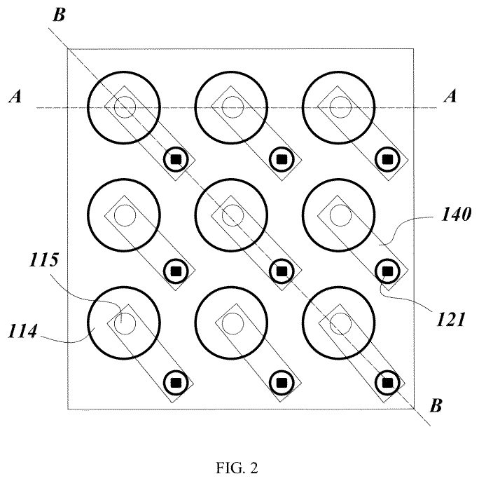

As shown in FIG. 1 and FIG. 2, a micro light emitting diode display device 100 is provided according to Example 1 of the present application. The micro light emitting diode display device 100 is obtained by a wafer level manufacturing process and cutting, where each micro light emitting diode display device 100 includes multiple LED units 110 capable of operating independently and arranged in an array.

The micro light emitting diode display device 100 includes an LED semiconductor layer. The LED semiconductor layer include a first doping type semiconductor layer 111, an active layer 112, and a second doping type semiconductor layer 113, where the active layer 112 is formed on the first doping type semiconductor layer 111, and the second doping type semiconductor layer 113 is formed on the active layer 112.

The LED semiconductor layer is provided with multiple protrusions 1131 arranged in an array. The multiple protrusions 1131 each includes an ion injection region 114 and a non-ion injection region, where the non-ion injection region forms an LED mesa 115, and the ion injection region 114 surround the LED mesa 115.

The non-ion injection region and the ion injection region 114 each has an arc-shaped light emitting surface capable of collimating light emitted from the LED unit.

In the example shown in FIG. 1, the protrusions 1131 are formed by the second doping type semiconductor layer 113, that is, the protrusions 1131 are formed on a surface of the active layer 112, and each of the protrusions 1131 combines with the active layer 112 and the first doping type semiconductor layer 111 to form an LED unit 110.

In some embodiments, the first doping type semiconductor layers 111 and the second doping type semiconductor layer 113 may include one or more layers formed of II-VI materials (such as ZnSe or ZnO) or III-V nitride materials (such as GaN, AlN, InN, InGaN, GaP, AlInGaP, AlGaAs, and alloys thereof).

In some embodiments, the first doping type semiconductor layer 111 may be p-type GaN. In some embodiments, the first doping type semiconductor layer 111 may be formed by doping magnesium (Mg) in GaN. In some embodiments, the first doping type semiconductor layer 111 may be p-type InGaN. In some embodiments, the first doping type semiconductor layer 111 may be p-type AlInGaP.

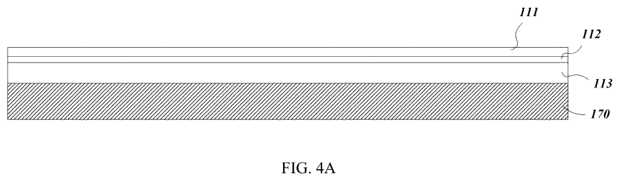

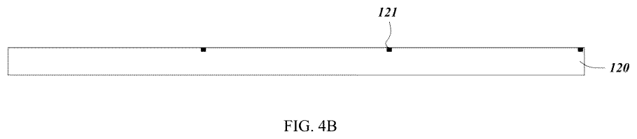

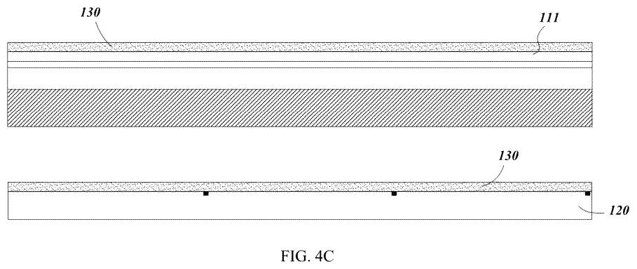

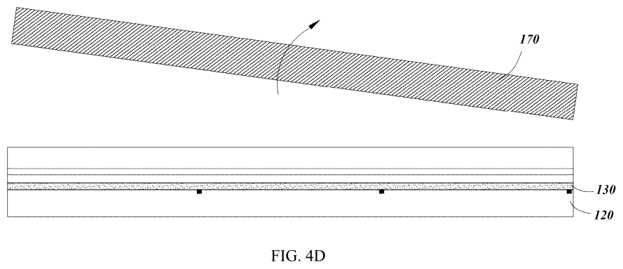

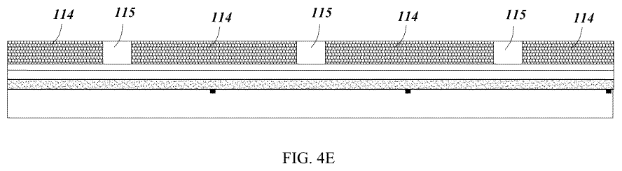

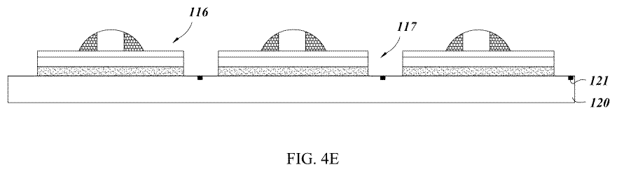

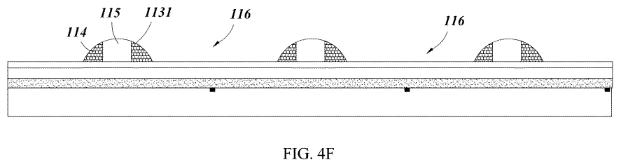

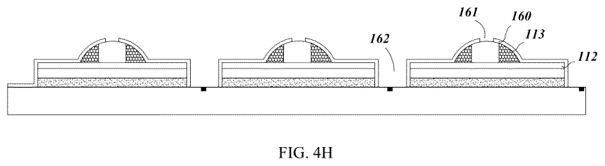

In some embodiments, the first doping type semiconductor layer 111 may be a p-type semiconductor layer extending across multiple LED units 110 (e.g., as shown in FIG. 4F) and forming a common anode of these LED units 110.

In some embodiments, the second doping type semiconductor layer 113 may be n-type GaN. In some embodiments, the second doping type semiconductor layer 113 may be n-type InGaN. In some embodiments, the second doping type semiconductor layer 113 may be n-type AlInGaP.

In some embodiments, the active layer 112 employs multiple quantum well layers (MQWs).

In some embodiments, the ion injection region 114 may be formed by injecting ions in the second doping type semiconductor layer 113. In some embodiments, the ion injection region 114 may be formed by injecting ions such as H+, He+, N+, O+, F+, Mg+, Si+, Ar+, or the like in the second doping type semiconductor layer 114. In some embodiments, the second doping type semiconductor layer 113 may be injected with one or more ions to form the ion injecting region 114. The ion injection region 114 has a physical property of being electrically insulated after injecting ions.

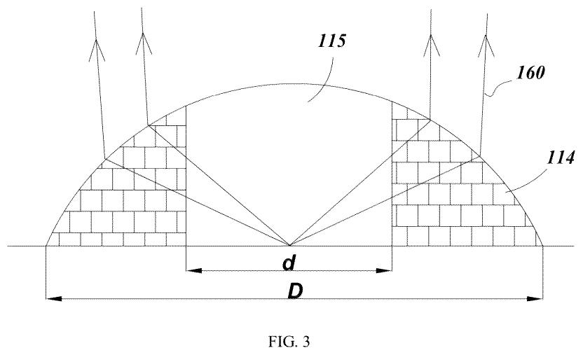

In each of the LED units 110, the second doping type semiconductor layer 113 has a protrusion 1131 for converging the emergent light. Referring to FIG. 2, each of the LED units 110 forms a micro-lens structure in a top view, and referring to FIG. 3, the emergent light 160 is refracted when passing through an arc-shaped light-exiting surface of the ion injection region 114, so as to achieve a converging effect.

In an embodiment, the entire light-emitting surface of the protrusion 1131 is an arc-shaped light-emitting surface, and the edge of the arc-shaped light-emitting surface extends to a top surface of the active layer 112. Referring to FIG. 4F, the second doping type semiconductor layer 113 is etched, so that the edge of the arc light-emitting surface extends to the surface of the active layer 112.

In an embodiment, the light-emitting surface corresponding to the LED mesa 115 may also be a plane, and the light-emitting surface corresponding to the ion injection area 114 is an arc-shaped light-emitting surface. The light is refracted when passing through the arc-shaped light-emitting surface and being emitted, so as to form a collimation effect, and an edge of the arc-shaped light-emitting surface extends to the active layer 112.

In a preferred embodiment, an axis of the LED mesa 115 is perpendicular to a plane at which the second doping type semiconductor layer 113 is located, and a cross section of the LED mesa 115 may be circular, and may also be other regular or irregular shapes such as rectangular and the like. In some embodiments, the LED mesa 115 is disposed in a central location of the LED unit 110. In some embodiments, the LED mesa 115 of each of the LED units 110 is circular in cross-section.

Referring to FIG. 3, in order to improve the convergence effect of the emergent light, in a preferred embodiment, an outer diameter D of the protrusion and an outer diameter d of the LED mesa satisfy: d is less than D/2.

An isolation groove 16 is formed on the second doping type semiconductor layer 113 between the adjacent LED units. In one embodiment of the present application, the isolation groove 116 is formed by an etching process, and the isolation groove 116 separates the second doping type semiconductor layer 113 into multiple independent microlens structures. By controlling a depth of the etching, a bottom portion of the isolation groove exposes the active layer 112.

When the bottom portion of the isolation groove 116 is etched to the surface of the active layer 112, the active layer 112 and the first doping type semiconductor layer 111 extend between the multiple LED units.

The second doping type semiconductor layers 113 of the different LED units 110 are electrically isolated by the isolation grooves 116, and thus each of the LED units 110 may have a cathode of a voltage level different from that of the other units. As a result of the disclosed embodiment, multiple individually operable LED units 110 are formed, where the first doping type semiconductor layer 111 of which extends horizontally across the adjacent LED units, and the second doping type semiconductor layer 113 of which is electrically isolated between the adjacent LED units.

The micro light emitting diode display device 100 further includes a substrate 120 and a bonding layer 130, where the bonding layer 130 is formed on a surface of the substrate 120, and the first doping type semiconductor layer 111 in the LED semiconductor layers is bonded to the substrate 120 through the bonding layer 130.

The substrate 120 includes driving circuits and multiple contacts 121 electrically connected to the driving circuit, where the contacts 121 are located in a gap between the adjacent LED units 110 and electrically connected to the second doping type semiconductor layer 113 of one of the LED units 110 through an electrode connection structure. In some embodiments of the present application, the second doping type semiconductor layer 113 forms a cathode of each of the LED units 110, and thus the contact 121 supplies a driving voltage corresponding to each of the LED units 110 from the driving circuit to the second doping type semiconductor layer 113 through the electrode connection structure.

The substrate 120 refers to a material on which subsequent layers of material are added. The substrate itself may be patterned. The material added on a top portion of the substrate may be patterned or may remain unpatterned. In some embodiments, the substrate may include a semiconductor material such as silicon, silicon carbide, gallium nitride, germanium, gallium arsenide, indium phosphide. In some embodiments, the substrate may be made of a non-conductive material, such as glass, plastic, or sapphire wafers. In some embodiments, the substrate may have a driving circuit formed therein, and the substrate may be a CMOS bottom plate or a TFT glass substrate. The driving circuit supplies an electrical signal to the LED unit to control brightness. In some embodiments, the driving circuit may include an active matrix driving circuit, where each individual LED unit corresponds to a separate driver. In some embodiments, the driving circuit may include a passive matrix driving circuit in which the multiple LED units are arranged in an array and connected to a data line and a scan line driven by the driving circuit.

Each of the LED units 110 has an anode and a cathode connected to the driving circuit, for example, formed in the substrate 120 (the driving circuit is not explicitly shown). For example, each of the LED units 110 has an anode connected to a constant voltage source and has a cathode connected to a source/drain of the driving circuit. In other words, by forming a continuous first doped semiconductor 111 across the separate LED units 110, the multiple LED units 110 have a common anode formed by the continuous first doping type semiconductor layer 111 and the continuous bonding layer 130.

The bonding layer 130 is an adhesive material layer formed on the substrate 120 to bond the substrate 120 and the LED unit 110. In some embodiments, the bonding layer 130 may be, for example, a metal or metal alloy. In some embodiments, the bonding layer 130 may include Au, Sn, Cu, and the like, and is limited thereto. In some embodiments, the bonding layer 130 may include a non-conductive material, such as Polyimide (PI), Polydimethylsiloxane (PDMS), and the like, which is no limited thereto. In some embodiments, the bonding layer 130 may include a photoresist, such as SU-8 photoresist, and the like, which is no limited thereto. In some embodiments, the bonding layer 130 may be Hydrogen Silsesquioxane (HSQ), divinylsiloxane-bis-benzocyclobutene (DVS-BCB), or the like, and is not limited thereto. It is to be understood that the description of the material of the bonding layer 130 is merely illustrative and is not limited, and that variations may be made as desired by those skilled in the art, all of which are within the scope of the present application.

In some embodiments, the first doping type semiconductor layer 111 extending across the LED unit may be relatively thin. By having a continuous thin layer of the first doped semiconductor on each of the LED units 110, a bonding region between the substrate 120 and the multiple LED units 110 is not limited to the region under the second doping type semiconductor layer, but extends to the region between each of the LED units. In other words, by having a thin layer of the continuous first doped semiconductor, an area of the bonding layer 130 is increased. Therefore, the bonding strength between the substrate 102 and the multiple LED units 110 is enhanced, and a risk of peeling off the LED structure can be reduced.

Each of the LED units 110 further includes a conductive layer (not shown) formed between the bonding layer 130 and the first doping type semiconductor layer 111. In some embodiments, the conductive layer adopts ITO (indium tin oxide).

The electrode connection structure includes multiple through holes 117 passing through the LED semiconductor layer and the bonding layer 130. Each of the through holes 117 corresponds to one contact 121, and the contact 121 is exposed at the bottom portion of the through hole 117.

In this embodiment, the through hole 117 is a straight hole passing through the second doping type semiconductor layer 113, the active layer 111 and the bonding layer 130, and the straight hole has a vertical sidewall extending from a lower surface of the bonding layer 130 to a top surface of the second doping type semiconductor layer 113. In this embodiment, the through hole 117 is etched through the second doping type semiconductor layer 113, the active layer 111, and the bonding layer 130 in sequence by one-time etching to expose the contact 121.

The electrode connection structure further includes a passivation layer 160 formed on the second doping type semiconductor layer 113, where the passivation layer 160 is opened with a first opening 161 exposing the LED mesa 115 and a second opening 162 exposing the contact 121.

The electrode connection structure further includes an electrode layer 140, which is formed on the passivation layer 160, and electrically connected to the second doping type semiconductor layer 113 through the first opening 161 and electrically connected to the contact 121 through the second opening 162.

In the example shown in FIG. 1, the first opening 161 is located at a center of each of the LED units. It is to be understood that the locations and designs (such as shapes and sizes) of the first opening 161, the second opening 162, and the electrode layer 140 may deviate from the example shown in FIG. 1 based on the specific embodiment and are not limited thereto.

The electrode layer 140 may be a transparent conductive material such as Indium Tin Oxide (ITO), Cr, Ti, Pt, Au, Al, Cu, Ge, Ni, or the like, and is limited thereto.

In some embodiments, the passivation layer 160 may include SiO2, Al2O3, SiN, or other suitable material for isolation and protection. In some embodiments, the passivation layer 160 may comprise polyimide, SU-8 photoresist, or other lithographically patternable polymers.

In summary, in the present application, each of the contacts is correspondingly connected to the second doping type semiconductor layer 113 of one LED unit, so as to realize independent control of each of the LED units. The first doping type semiconductor layer 111 extends between the multiple LED units, thus implementing a common electrode.

In this embodiment, the N pole of each of the LED units is driven separately, and all of the LED units share the P pole. In other embodiments of the present application, the P pole of each of the LED units may be driven separately, and all the LED units share the N pole.

As shown in FIG. 4A to FIG. 4H, a method for manufacturing the micro light emitting diode display device 100 according to a first embodiment of the present application is provided.

Referring to FIG. 4A, an LED epitaxial wafer is provided, which includes a first substrate 170 and an LED semiconductor layer, where the LED semiconductor layer includes a second doping type semiconductor layer 113, an active layer 112 and a first doping type semiconductor layer 111, which are sequentially formed on the first substrate 170.

the first substrate 170 serves as a growth carrier for the epitaxial layers, which may adopts sapphire, silicon carbide, silicon, and the like.

A conductive layer (not shown) is formed on a surface of the first doping type semiconductor layer 111 to serve as a common electrode layer. In some embodiments, the conductive layer adopts ITO (indium tin oxide).

Referring to FIG. 4B, a substrate 120 is provided, and the substrate 120 includes driving circuits and multiple contacts 121 electrically connected to the driving circuit.

Referring to FIG. 4C, a bonding layer 130 is formed on the substrate 120 and the surface of the first doping type semiconductor layer 111.

Referring to FIG. 4D, the LED epitaxial wafer is inverted and bonded to the substrate 120 through the bonding layer 130, and then the first substrate 170 is peeled off and removed.

Referring to FIG. 4E, an ion injection operation is performed to form an ion injection region 114 in the second doping type semiconductor layer 113, the ion injection region 114 divides the second doping type semiconductor layer 113 into multiple LED mesas isolated from each other, and the ion injection region 114 respectively encloses an LED mesa 115 extending along a light emitting direction corresponding to each of the LED mesas.

In some embodiments, the injection operation is performed with an ion injection power between about 10 keV and about 300 keV In some embodiments, the injection operation may be performed at an ion injection power between about 15 keV and about 250 keV In some embodiments, the injection operation may be performed at an ion injection power between about 20 keV and about 200 keV In some embodiments, the injected ions include hydrogen, helium, nitrogen, oxygen, fluorine, magnesium, silicon, or argon ions.

In some embodiments, the ion injection region 114 may be formed in the second doping type semiconductor layer 113, with a depth insufficient to pass through the active layer 112. The active layer 112, the first doping type semiconductor layer 111, and the bonding layer 130 under each of the LED mesas may horizontally extend to the active layer 112, the first doping type semiconductor layer 111, and the bonding layer 130 under the adjacent LED mesas.

Referring to FIG. 4F, an etching operation is performed to remove a portion of the ion injection region 114, forming isolation grooves 116 between the adjacent LED mesas, and the corresponding LED mesa are etched to form a protrusion 1131 for converging light. From a top view, an array of microlens structures is formed on the substrate, where each of the microlens structures includes an ion injection region 114 in a ring shape, and an LED mesa 115 surrounded in a middle portion by the ion injection region 114.

Referring to FIG. 4G, a through hole 117 is further etched to the bottom portion of the isolation groove 116, and the bottom portion of the through hole 117 exposes a contact 121 formed on the substrate 120.

Specifically, a method for forming the through hole 117 includes: at the bottom surface of the isolation groove 116 and corresponding to the contact, the active layer 112, the first doping type semiconductor layer 111 and the bonding layer 130 are sequentially etched through by one-time etching to expose the contact 121.

Referring to FIG. 4H, a passivation layer 160 is formed on the surface of the active layer 112, the surface of the second doping type semiconductor layer 113, and the sidewall of the groove, and a first opening 161 is opened at a position of the passivation layer 160 corresponding to the LED mesa 115, where the first opening 161 exposes the top surface of the LED mesa 115. A second opening 162 is opened at a position corresponding to the contact 121 to expose the contact 121.

Then, an electrode layer 130 is formed on the passivation layer 160, in the first opening 161 and in the second opening 162, so that the electrode layer 130 is connected between the contact 121 and the second doping type semiconductor layer 113 to form the micro light emitting diode display device 100 as shown in FIG. 1.

### Example 2

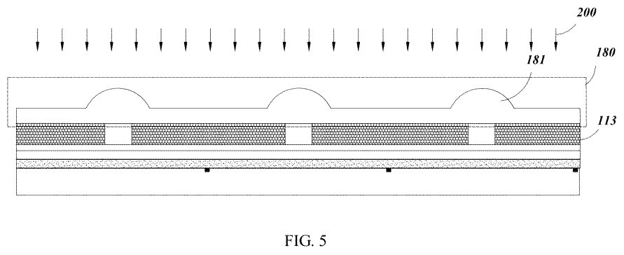

After completing the structure of FIG. 4E, the manufacturing of the microlens structure may also use a dry etch pattern transfer, as shown in FIG. 5, to provide a precursor layer 180, which precursor layer 180 has been processed to produce a microlens shaped precursor 181. The precursor layer 180 may be shaped by using different techniques, and the material of the precursor layer 180 may be any semiconductor material that can be dry etched. For example, in an embodiment, the same material as the second doping type semiconductor layer 113 may be used. The precursor layer 180 is formed on the surface of the second doping type semiconductor layer 113 and then a dry plasma etch 200 is applied to the precursor layer 180, which transfers the lens shaped precursor 181 of the precursor layer 180 to the underlying second doping type semiconductor layer 113, thereby forming the structure of the protrusion 1131 arranged in an array as shown in FIG. 4F.

### Example 3

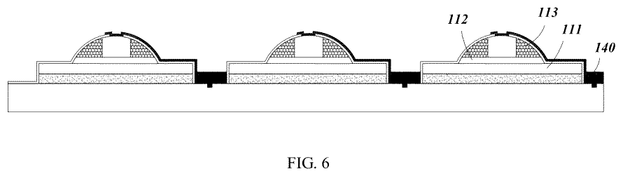

Referring to FIG. 6, a lens structure may be formed on a surface of the first doping type semiconductor layer 111. Specifically, the edge of the arc-shaped light-emitting surface is extended to the surface of the first doping type semiconductor layer 111 by etching the second doping type semiconductor layer 113 and the active layer 112. Other structures and manufacturing methods are the same as those in Example 1, and will not be described again.

### Example 4

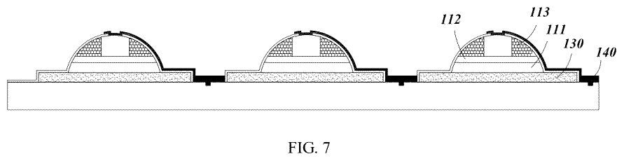

Referring to FIG. 7, a lens structure may be formed on a surface of the bonding layer 130. Specifically, the second doping type semiconductor layer 113, the active layer 112 and the first doping type semiconductor layer 111 are etched, so that the edge of the arc-shaped light-emitting surface extends to the surface of the bonding layer 130. Other structures and manufacturing methods are the same as those in Example 1, and will not be described again.

### Example 5

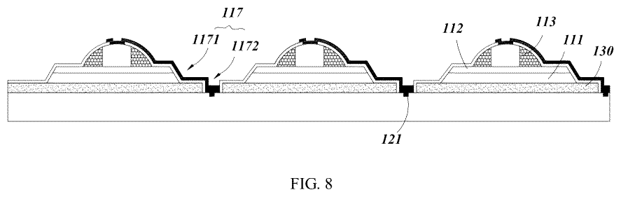

Referring to FIG. 8, the through holes 117 may also be in stepped shape. The through hole 117 passes through the LED semiconductor layer and the bonding layer 130, one contact 121 corresponds to each through hole 117, and the contact 121 is exposed at the bottom portion of the through hole 117.

In this embodiment, the through hole 117 includes a first through hole 1171 passing through the LED semiconductor layer and exposing a surface of the bonding layer 130, and further includes a second through hole 1172 passing through the bonding layer 130 and exposing a contact, and the first through hole 1171 and the second through hole 1172 are communicated with each other and are in stepped shape.

The method for manufacturing the stepped through hole 117 includes the following steps:

step 1: forming a first through hole 1171 on the LED semiconductor layer at a position corresponding to the contact 121 by using an etching process, where the bottom portion of the first through hole 1171 exposes the bonding layer 130, and the first through hole 1171 has an inclined side wall.

Step 2: forming a second through hole 1172 on the bonding layer 130 at a position corresponding to the contact 121 by using an etching process, where the contact 121 is exposed at the bottom portion of the second through hole 1172, and the second through hole 1172 has vertical sidewalls.

Other structures and manufacturing methods are the same as those in Example 1, and will not be described again.

### Example 6

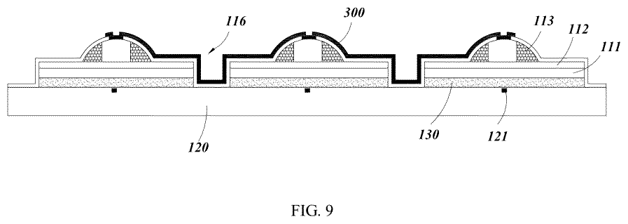

Referring to FIG. 9, in the present embodiment, the isolation groove 116 is formed between the adjacent LED units, and the surface of the substrate 120 is exposed. The isolation groove 116 electrically isolates the second doping type semiconductor layer 113, the active layer 112, the first doping type semiconductor layer 111, and the bonding layer 130 of different LED units 110, so that multiple mesa structures with independent structures are formed on the substrate 120. The contact 121 is located below the corresponding LED unit 110 and electrically connected to the first doping type semiconductor layer 111 through the conductive bonding layer 130, so that the contact 121 provides a driving voltage corresponding to each LED unit 110 from a driving circuit to the first doping type semiconductor layer 111 through the bonding layer 130, the second doping type semiconductor layers 113 of the multiple LED units 110 are connected through the electrode layer 300, and the electrode layer 300 is used as a common electrode, preferably adopting ITO (indium tin oxide).

Other structures and manufacturing methods are the same as those in Example 1, and will not be described again.

The foregoing description of specific exemplary embodiments of the present application has been presented for the purposes of illustration and description. It is not intended to limit the present application to the precise form disclosed, and obviously many modifications and variations are possible in light of the above teaching. The exemplary embodiments were chosen and described in order to explain certain principles of the present application and its practical application to enable one skilled in the art to make and use various exemplary embodiments of the present application and various alternatives and modifications. It is intended that the scope of the v application be defined by the claims and their equivalents.

What is claimed is:

1. A micro light emitting diode (LED) display device, comprising an LED semiconductor layer, wherein the LED semiconductor layer comprising:
a first doping type semiconductor layer;
an active layer formed on the first doping type semiconductor layer;
a second doping type semiconductor layer formed on the active layer;
wherein the LED semiconductor layer is provided with a plurality of protrusions arranged in an array, and each of the protrusions corresponds to one LED unit,
the protrusion comprises an ion injection region and a non-ion injection region, wherein the non-ion injection region forms an LED mesa, the ion injection region surrounds the LED mesa, and the protrusion is provided with an arc-shaped light emitting surface capable of collimating light emitted by the active layer.

2. The micro light emitting diode display device according to claim 1, wherein the protrusions are formed by the second doping type semiconductor layer,
and each of the protrusions is combined with the active layer and the first doping type semiconductor layer to form an LED unit.

3. The micro light emitting diode display device according to claim 1, wherein the protrusions are formed by the second doping type semiconductor layer and the active layer,
and each of the protrusions is combined with the first doping type semiconductor layer to form an LED unit.

4. The micro light emitting diode display device according to claim 1, wherein the protrusions are formed by the second doping type semiconductor layer, the active layer and the first doping type semiconductor layer,
and each of the protrusions forms an LED unit.

5. The micro light emitting diode display device according to claim 1, further comprising a substrate, wherein the LED semiconductor layer is arranged on the substrate through a bonding layer, and the bonding layer is formed between the substrate and the first doped semiconductor;
the substrate comprises a driving circuit and a plurality of contacts electrically connected with the driving circuits, each of the LED units corresponds to one contact, and the contacts drive the LED units.

6. The micro light emitting diode display device according to claim 5, wherein the contact is electrically connected with the second doping type semiconductor layer of each LED unit,
and the contacts are located between the adjacent LED units, and the micro light emitting diode display device further comprises an electrode connection structure, and the contacts are electrically connected with the second doping type semiconductor layer of the LED units through an electrode connection structure.

7. The micro light emitting diode display device according to claim 6, wherein the electrode connection structure comprises:
a plurality of through holes passing through the LED semiconductor layer and the bonding layer, where each of the through holes corresponds to one of the contacts, and the contacts are exposed at the bottom of the through holes;
a passivation layer formed on the second doping type semiconductor layer, wherein a first opening exposing the LED mesa and a second opening exposing the contacts are formed on the passivation layer;
an electrode layer formed on the passivation layer, and electrically connected to the second doping type semiconductor layer through the first opening and electrically connected to the contact through the second opening.

8. The micro light emitting diode display device according to claim 7, wherein the through hole comprises a first through hole passing through the LED semiconductor layer and exposing a surface of the bonding layer, and wherein
the through hole further comprises a second through hole passing through the bonding layer and exposing the contact,
the first through hole and the second through hole are communicated with each other.

9. The micro light emitting diode display device according to claim 7, wherein the through hole is a straight hole passing through the LED semiconductor layer and the bonding layer.

10. The micro light emitting diode display device according to claim 5, wherein an isolation groove is formed between the adjacent LED units, and the isolation groove passes through the LED semiconductor layer and the bonding layer for electrical isolation,
each of the contacts is located below a corresponding LED unit and electrically connected with the first doping type semiconductor layer through the conductive bonding layer, and
the second doping type semiconductor layers of the plurality of LED units share an electrode through an electrode layer.

11. A method for manufacturing a micro light emitting diode display device, comprising:
providing a first substrate, and forming an LED semiconductor layer on the first substrate, wherein the LED semiconductor layer comprises a second doping type semiconductor layer, an active layer and a first doping type semiconductor layer which are sequentially formed;
providing a substrate, wherein the substrate comprises a driving circuit and a plurality of contacts electrically connected with the driving circuits;
arranging a bonding layer on the substrate and/or the first doping type semiconductor layer;
bonding the substrate and the first doping type semiconductor layer with each other through the bonding layer;
peeling off and removing the first substrate and then performing an ion injection operation to form an isolation material in the LED semiconductor layer, wherein the isolation material divides the LED semiconductor layer into a plurality of LED mesas; and
performing an etching operation to form a plurality of protrusions arranged in an array on the LED semiconductor layer, wherein each of the protrusions comprises the LED mesas and an ion injection region surrounded by the isolation material, and the protrusions are provided with arc-shaped light-emitting surfaces capable of collimating the light emitted by the active layer.

12. The method for manufacturing a micro light emitting diode display device according to claim 11, wherein a method for forming a plurality of protrusions arranged in an array on the LED semiconductor layer comprises:
etching the second doping type semiconductor layer to the surface of the active layer or a certain depth thereof, forming the protrusions on the active layer, and combining each of the protrusions with the active layer and the first doping type semiconductor layer to form an LED unit.

13. The method for manufacturing a micro light emitting diode display device according to claim 11, wherein the method for forming a plurality of protrusions arranged in an array on the LED semiconductor layer comprises:
etching the second doping type semiconductor layer to the surface of the first doping type semiconductor layer or a certain depth thereof, forming the protrusions on the first doping type semiconductor layer, and combining each of the protrusions with the first doping type semiconductor layer to form an LED unit.

14. The method for manufacturing a micro light emitting diode display device according to claim 11, wherein the method for forming a plurality of protrusions arranged in an array on the LED semiconductor layer comprises:
etching the second doping type semiconductor layer to the surface of the bonding layer, and forming the protrusions on the surface of the bonding layer, wherein each of the protrusions forms an LED unit.

15. The method for manufacturing a micro light emitting diode display device according to claim 11, wherein the contacts are located between the adjacent protrusions, and
the method further comprises manufacturing an electrode connection structure, and the contact is electrically connected with the second doping type semiconductor layer of the protrusion through the electrode connection structure.

16. The method for manufacturing a micro light emitting diode display device according to claim 15, wherein a method for manufacturing the electrode connection structure comprises:
etching the LED semiconductor layer and the bonding layer to form a plurality of through holes distributed in an array, wherein each of the through holes corresponds to one contact, and the contacts are exposed at the bottom portion of each through hole;
forming a passivation layer on the second doping type semiconductor layer, wherein the passivation layer is provided with a first opening exposing the LED mesa and a second opening exposing the contacts; and
forming an electrode layer on the passivation layer, and the electrode layer is electrically connected with the second doping type semiconductor layer through the first opening and electrically connected with the contact through the second opening.

17. The method for manufacturing a micro light emitting diode display device according to claim 16, wherein a method for forming a plurality of through holes distributed in an array on the LED semiconductor layer and the bonding layer comprises:
forming a first through hole between the adjacent protrusions by sequentially etching the active layer and the first doping type semiconductor layer;
etching the bonding layer at the bottom portion of the first through hole to form a second through hole, exposing the contact, and communicating with the first through hole.

18. The method for manufacturing a micro light emitting diode display device according to claim 16, wherein the method for forming the plurality of through holes in an array distribution on the LED semiconductor layer and the bonding layer comprises:
passing through the active layer, the first doping type semiconductor layer and the bonding layer respectively through one-time etching between adjacent LED units.

19. The method for manufacturing a micro light emitting diode display device according to claim 11, wherein the contact is located below the corresponding LED unit and electrically connected with the first doping type semiconductor layer through a conductive bonding layer, and wherein
the method further comprises:
forming an isolation groove between the adjacent LED units, wherein the isolation groove passes through the active layer, the first doping type semiconductor layer and the bonding layer for electrical isolation, and
manufacturing an electrode layer between the second doping type semiconductor layers of a plurality of LED units, and the electrode layer is used as a common electrode.

20. The method for manufacturing a micro light emitting diode display device according to claim 11, wherein the method for forming a plurality of protrusions arranged in an array on the LED semiconductor layer comprises:
manufacturing a precursor layer on the surface of the formed second doping type semiconductor layer, wherein the precursor layer is formed with a precursor matched with the shape of the protrusion; and
etching the precursor layer and the LED semiconductor layer to transfer the shape of the precursor of the precursor layer from the precursor layer to the LED semiconductor layer.
